(19) United States
(12) Patent Application Publication
(10) Pub. No.: US 2025/0380437 A1
(43) Pub. Date: Dec. 11, 2025

(54) METHOD FOR MANUFACTURING A VERTICAL RF BIPOLAR TRANSISTOR, VERTICAL RF BIPOLAR TRANSISTOR, AND SEMICONDUCTOR DEVICE

(71) Applicant: Infineon Technologies AG, Neubiberg (DE)

(72) Inventors: Dmitri Alex TSCHUMAKOW, Dresden (DE); Claus DAHL, Dresden (DE); Vladislav KOMENKO, Dresden (DE); Steffen ROTHENHÄUßER, Dresden (DE); Steffen BIESELT, Wehlen (DE); Momtchil STAVREV, Dresden (DE)

(21) Appl. No.: 19/220,326

(22) Filed: May 28, 2025

(30) Foreign Application Priority Data
Jun. 7, 2024 (DE) 102024205252.3

(51) Int. Cl. H10D 10/40; H01L 23/66; H10D 10/01; H10D 62/13; H10D 62/17; H10D 62/40; H10D 64/23; H10D 64/27

(52) U.S. Cl. CPC H10D 10/40; H01L 23/66; H10D 10/051; H10D 62/133; H10D 62/177; H10D 62/40; H10D 64/231; H10D 64/281; H01L 2223/6605

(57) ABSTRACT

A method of manufacturing a vertical RF bipolar transistor includes fabricating a structure, the structure including a collector formed in a substrate, a base arranged above the collector, an emitter arranged above the base, a sidewall spacer extending in a vertical direction on a sidewall of the emitter, a first layer, wherein a first portion of the first layer is arranged on the sidewall spacer such that in a lateral direction the sidewall spacer is between the emitter and the first layer and wherein an outer sidewall of the first portion of the first layer is exposed, wherein the first layer directly contacts the base in the vertical direction and in the lateral direction, and a conductive layer extending in the lateral direction. In the fabricated structure, a second portion of the first layer is arranged in the lateral direction between the base and the conductive layer.

### CROSS-REFERENCE TO RELATED APPLICATION

This application claims priority to Germany Patent Application No. 102024205252.3 filed on Jun. 7, 2024, the content of which is incorporated by reference herein in its entirety.

### TECHNICAL FIELD

The present disclosure relates to manufacturing of vertical RF bipolar transistors.

### BACKGROUND

In many applications, such as in the field of radar, wireless communication or medical applications, vertical radio frequency (RF) bipolar transistors are used for generating signals having frequencies in the GHz-regime or even above. In future applications, the maximum operation frequency of vertical RF bipolar transistors may rise to higher values. Such future challenges require the vertical RF bipolar transistor to be capable of achieving high maximum operation frequencies and a high performance. It is desirable to have a concept that allows to manufacture vertical RF bipolar transistors with improved operation characteristics.

### SUMMARY

According to one aspect, a method of manufacturing a vertical RF bipolar transistor includes fabricating a structure, the structure including a collector formed in a substrate, a base arranged above the collector, an emitter arranged above the base, a sidewall spacer extending on a sidewall of the emitter, a first layer, wherein a first portion of the first layer is arranged on the sidewall spacer such that in a lateral direction the sidewall spacer is between the emitter and the first layer and wherein an outer sidewall of the first portion of the first layer is exposed, wherein the first layer directly contacts the base in the vertical direction and in the lateral direction, and a conductive layer extending in the lateral direction. In the fabricated structure, a second portion of the first layer is arranged in the lateral direction between the base and the conductive layer. After fabricating the structure, at least the second portion of the first layer is removed to form a space between the base and the conductive layer and semiconductor material is deposited in the space to connect the base with the conductive layer.

According to a further aspect, a vertical RF bipolar transistor includes a substrate having a first main surface and a collector arranged in the substrate. A base is arranged above the collector, an emitter is arranged above the base and a sidewall spacer is arranged lateral to the emitter. An insulation layer is arranged above the first main surface of the substrate. The vertical RF bipolar transistor includes a base connection, wherein the base connection extends in a lateral direction on the insulation layer. A conductive interface region electrically connects the base connection with the base. The conductive interface region includes monocrystalline semiconductor material. The base and the conductive interface region overlap in a top view and the conductive interface region is not in direct contact with an upper surface of the base.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A to 1Y illustrate schematic cross-sectional views of an example of a manufacturing process to manufacture a vertical RF bipolar transistor.

FIG. 2 shows a schematic cross-sectional view of an initial structure of a further example of a manufacturing process.

FIG. 3 shows a schematic cross-sectional view of an example of a vertical RF bipolar transistor.

FIG. 4 shows a schematic cross-sectional view of further example of a vertical RF bipolar transistor.

FIG. 5 shows a schematic cross-sectional view of a further example of a vertical RF bipolar transistor.

FIG. 6 shows a schematic cross-sectional view of a further example of a vertical RF bipolar transistor.

FIG. 7 shows a diagram of acts of an example manufacturing process.

### DETAILED DESCRIPTION

In the following examples will be described for a new concept for a vertical RF bipolar transistor. In the manufacturing of vertical RF bipolar transistors, such as heterojunction vertical RF bipolar transistors, an interface between a base and a base connection has significant impact on the performance of the vertical RF bipolar transistor. Imperfections that are introduced in the connection between the base and the base connection may lead to a deterioration of the performance of a vertical RF bipolar transistor. Furthermore, the base of vertical RF bipolar transistors is typically monocrystalline for performance reasons while the base connection is typically polycrystalline. To achieve high performance, a high degree of monocrystalline material is desired also in the interface region connecting the base with the base connection. Accordingly, connecting the monocrystalline base with the polycrystalline base connection is crucial and establishes challenges in such manufacturing processes. Another strong additional performance detractor of the RF bipolar transistor is the collector-base capacitance. Hence the area of the structural base-collector interface should be reduced to a necessary minimum value, avoiding the creation of parasitic parts which directly do not contribute to the current conduction. Also the parasitic capacitances between the base link and the collector should be reduced to the possible minimum.

The challenges are even increased for vertical RF bipolar transistors having a maximum operation frequency, fmax, of 600 GHz or 800 GHz or 1000 GHz or even more. Such vertical RF bipolar transistors require new approaches. Furthermore integration in a BiCMOS process in which in addition to the vertical RF bipolar transistor CMOS transistors are fabricated is desired.

The concept presented herein makes use of forming the interface region after the main parts of the vertical RF bipolar transistor (e.g., at least collector, base and emitter having the respective dopants and doping concentrations) have been formed. This self-aligned seed layer concept allows an easier and less complex approach. In addition the concept makes use of a defined layer (which may be regarded as a sacrificial layer or a sacrificial side spacer layer) which is removed to define a temporarily empty space between the base and the conductive layer. This concept allows to place the interface between the base and the conductive layer at the ideal position. The temporarily empty space is filled by depositing semiconductor material using epitaxial growing. The layer defining the space is contacting the base in a lateral and in a vertical direction. Consequently, when the layer is removed, lateral and vertical sidewall portions of the base are exposed allowing an epitaxial growing from the base into the empty space from monocrystalline base surfaces extending lateral and vertical. This allows to grow the semiconductor material connecting the base and the conductive layer at the desired location with high quality and a high degree of monocrystalline portions since the surface of monocrystalline material from which the growth can start is increased. Furthermore this concept also reduces parasitic capacitances as the interface from base to the conductive layer can be manufactured at the optimal position.

The combination of the above explained manufacturing steps establishes a new manufacturing of a high performance vertical RF bipolar transistor operating at very high frequencies with reduced manufacturing complexity and improved BiCMOS integration.

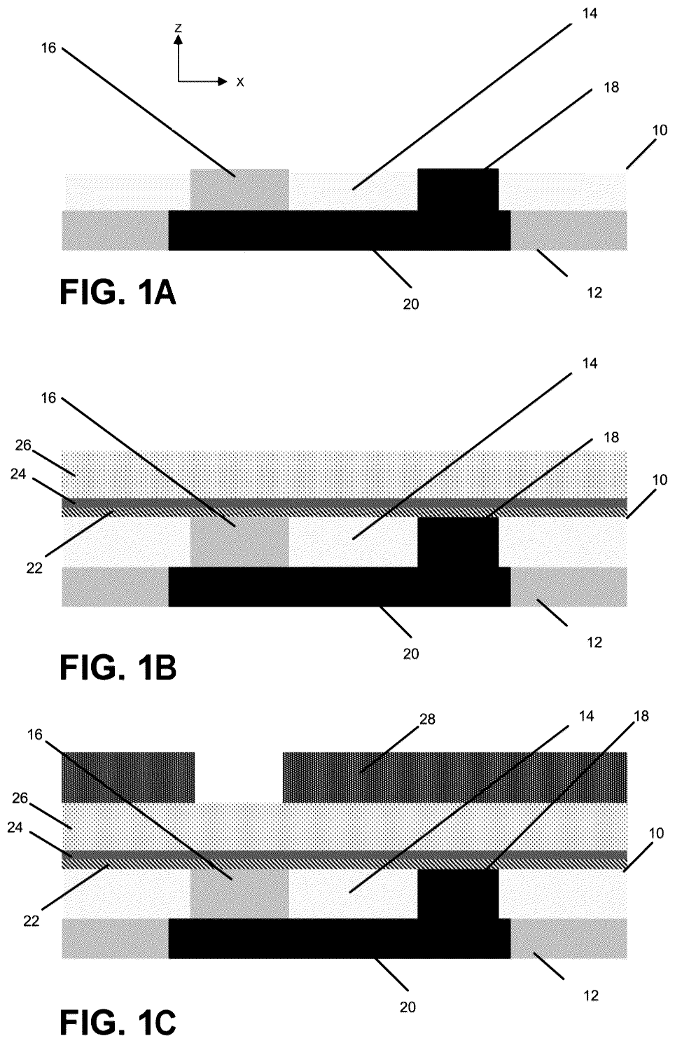

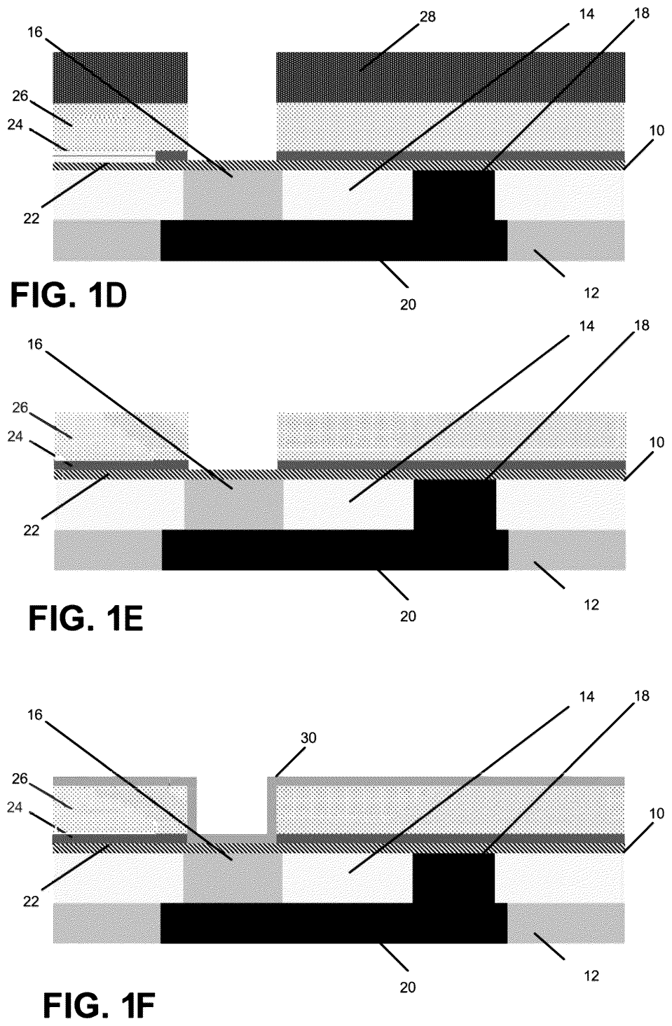

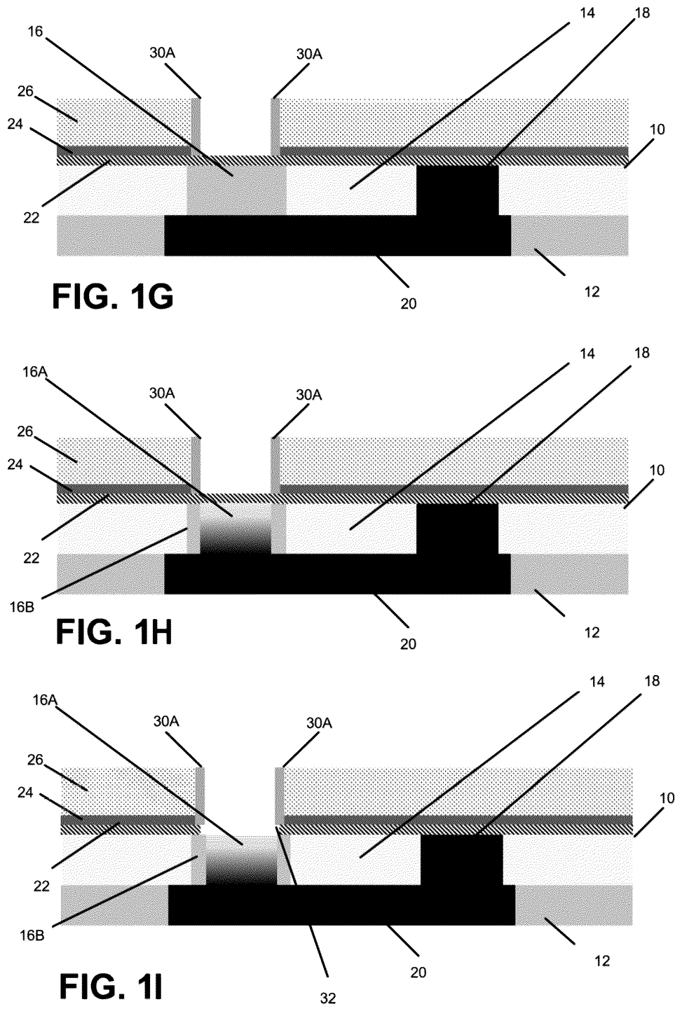

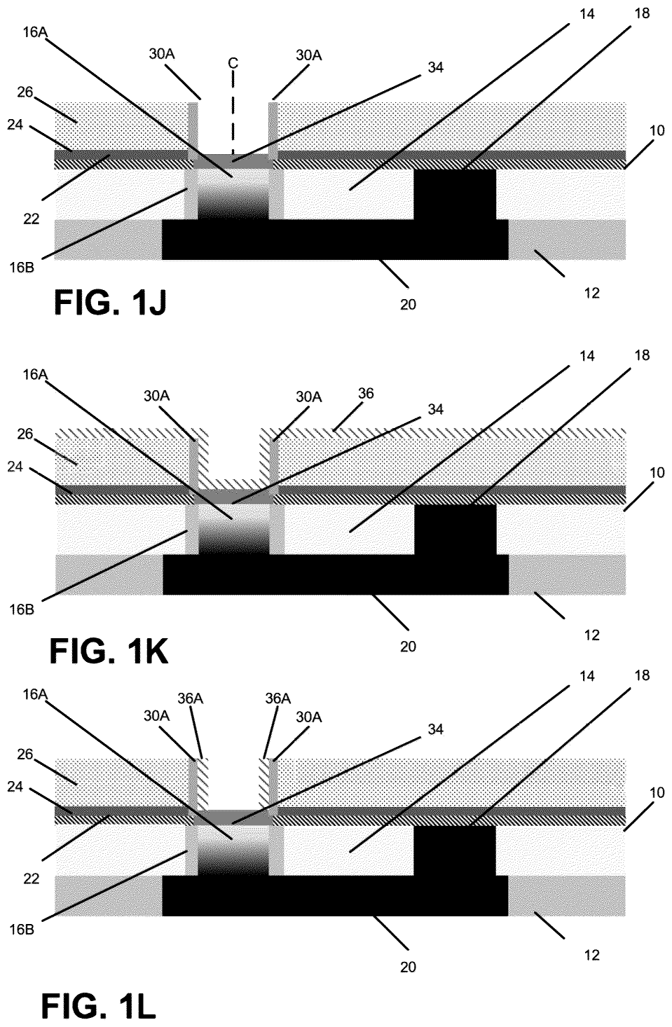

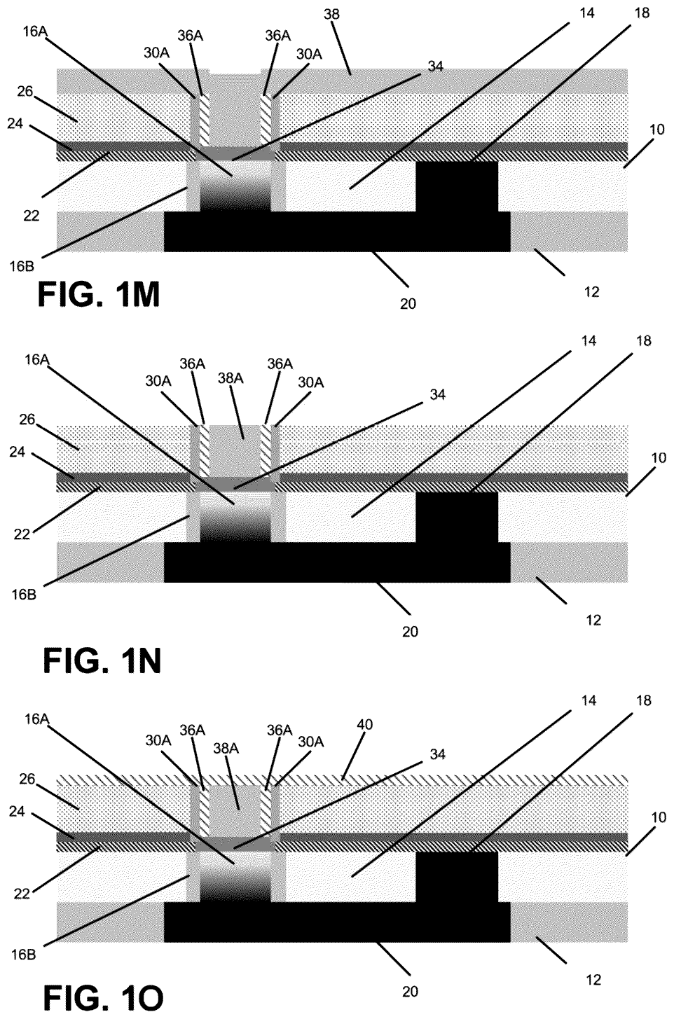

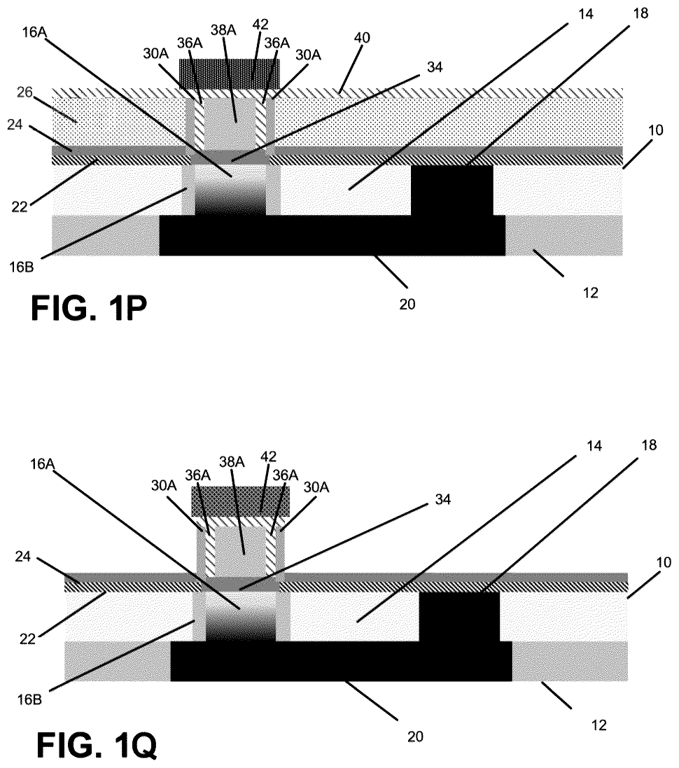

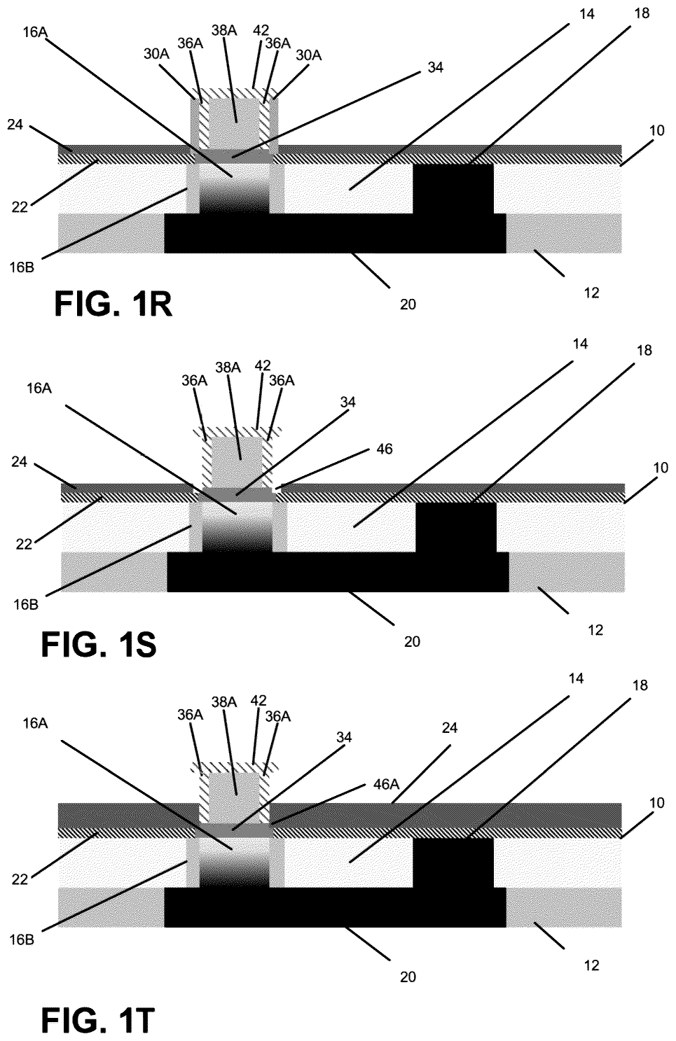

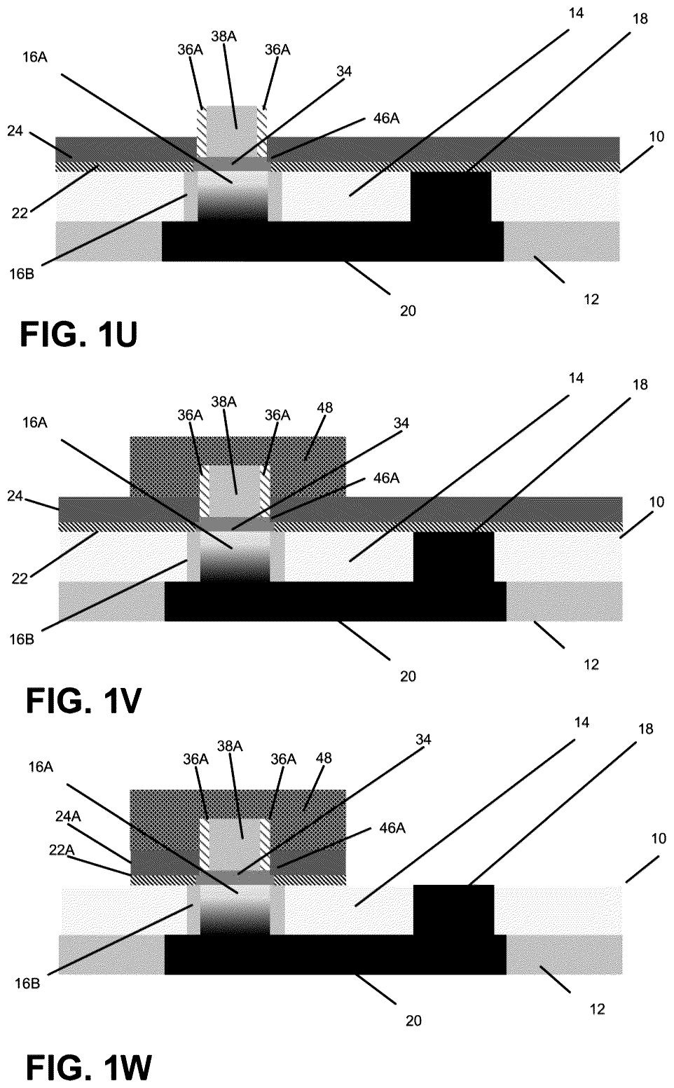

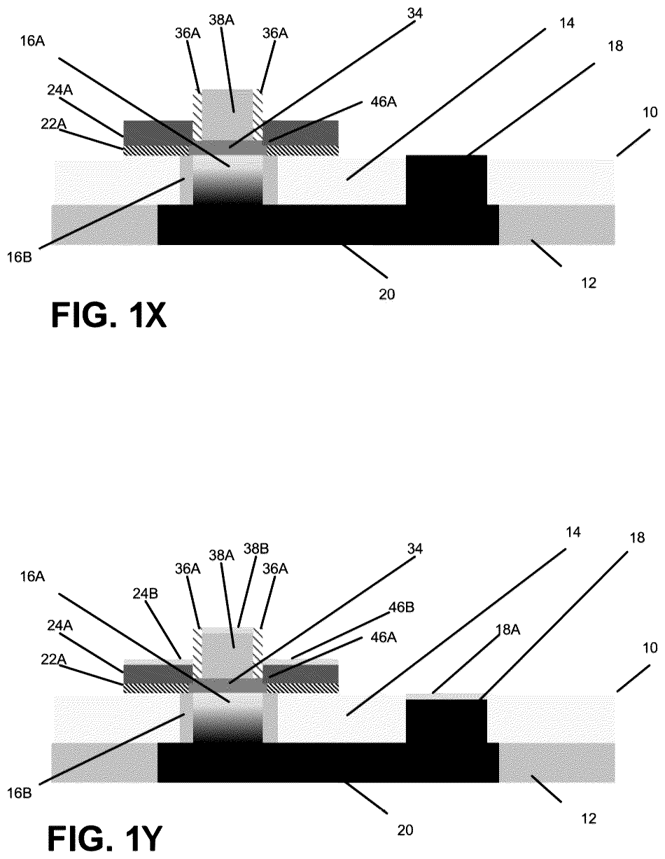

Referring now to FIGS. 1A to 1Y, an example of a process for manufacturing a vertical RF bipolar transistor will be explained. FIGS. 1A to 1Y show the process in a cross-sectional view of the illustrated structures. The described process is capable of manufacturing vertical RF bipolar transistors in a semiconductor device which are capable of operation in the extremely high frequency range (30 to 300 GHZ) or even in the tremendously high frequency range (300 GHz to 3 THz) of the radio spectrum. In some examples, the resulting vertical RF bipolar transistor is capable of operating in a frequency range above 250 GHz. In some examples the resulting vertical RF bipolar transistor is capable of operating in a frequency range above 300 GHz. Furthermore, the process may be integrated into a BiCMOS process allowing to generate the vertical RF bipolar transistor on a same die as CMOS transistors.

FIG. 1A shows a preprocessed initial substrate 10 which comprises a semiconductor material portion 12 as well as an insulation portion 14. The insulation portion 14 extends on the upper portion of the substrate 10 and comprises electrical insulating material such as semiconductor oxide material. The insulation portion 14 is arranged between a collector region 16 (sometimes referred to as collector sinker) and a collector connection region 18 and may surround the collector region 16 to provide electrical isolation. The collector region 16 and the collector connection region 18 comprise doped semiconductor material, e.g., doped monocrystalline silicon. The collector region 16 and/or the collector connection region 18 may be formed by implantation or epitaxial growing or a combination thereof. A collector connection layer 20 extends below the insulation portion 14 to electrically connect the collector region 16 with the collector connection region 18. In the example shown in FIG. 1A, the insulation may be a shallow trench isolation and the insulation portion 14 may include a shallow trench isolation oxide. However, the described concept is not limited thereto. In FIG. 1A, a main surface of the substrate 10 includes an upper surface of the insulation portion 14, the upper surface of the collector region 16 and the upper surface of the collector connection region 18. The upper surface of the insulation portion 14, the upper surface of the collector region 16 and the upper surface of the collector connection region 18 may be flush with each other as shown in FIG. 1A. The main surface extends in a lateral direction (in FIG. 1A shown as x-axis). A vertical direction perpendicular to the lateral direction is shown in FIG. 1A as z-axis. In the following, the terms “upper” or “above” or “top” refer to a relation of different levels or an orientation relative to the vertical direction. Similar, the terms “lower” or “below” or “bottom” refer to a relation of different levels or an orientation relative to the vertical direction.

Referring now to FIG. 1B, a stack of layer is deposited above the substrate 10. The stack of layer comprises a first insulation layer 22 in direct contact with the upper surface of the substrate 10, a conductive layer 24 above the first insulation layer 22 and a second insulation layer 26 above the conductive layer 24. The first insulation layer 22 and the second insulation layer 26 may be electrically insulating. The first insulation layer 22 may be a thin oxide layer in the range from 10 to 40 nm. The conductive layer 24 may be a heavily doped semiconductor layer, for example a p-doped polycrystalline silicon layer having a net doping concentration in a range from 1e19 to 5e20 cm-3. The thickness of the conductive layer 24 may be between 20 to 70 nm. As will be described below, a portion of the conductive layer 24 will later form a portion of a base connection. The second insulation layer 26 may be an oxide layer and may be thicker than the first insulation layer 22, for example in the range from 100 to 400 nm.

FIG. 1C shows the structure of FIG. 1B after depositing and structuring a lithography mask 28 to define an emitter window area. The structured lithography mask 28 is used for etching a cavity into the second insulation layer 26 and the conductive layer 24 to generate an emitter window in the emitter window area. FIG. 1D shows the structure of FIG. 1C after etching the emitter window. While the cavity may have vertical sidewalls as shown in FIG. 1D, it is to be understood that the cavity may have in some examples nearly vertical sidewalls (e.g., less than 15° deviation from the vertical direction). When etching the emitter window, the first insulation layer 22 remains in the emitter window area completely or at least partially. Accordingly, the etching is performed either selectively to stop at the upper surface of the first insulation layer 22 or is timed to stop within the first insulation layer 22. After forming the emitter window, the lithography mask 28 is removed, see FIG. 1E.

An electrically insulating spacer layer 30 is formed on the surface of the cavity and the upper surface of the second insulation layer 26, see FIG. 1F. The spacer layer 30 may in one example comprise nitride and may have a thickness less than 100 nm, in some examples between 20 to 60 nm. However other materials may be used for forming the spacer layer 30. The spacer layer 30 may in some examples also include a stack of layers. The spacer layer 30 is removed on the upper surface of the second insulation layer 26 and on the first insulation layer 22 in the emitter window area, see FIG. 1G. The remaining portion of the spacer layer 30 forms a first layer 30A extending on the sidewalls of the cavity in a similar shape as a sidewall spacer. As can be observed from FIG. 1G, the first layer 30A extends lateral to the side surfaces of the conductive layer 24 and the second insulation layer 26. The first layer 30A directly contacts lateral ends of the conductive layer 24 and the second insulation layer 26.

The first layer 30A can be regarded as a sacrificial sidewall spacer which is removed later on to form a space. In the cross-sectional view, two portions of the first layer 30A are illustrated which are opposing each other. The portions of the first layer 30A may be separate to each other or may be connected to each other. In the described examples, the first layer 30A completely surrounds the emitter region in a top view. As will be described later on, the first layer 30A provides protection for the conductive layer 24 in following manufacturing steps and is used for defining an interface area for the base link. Furthermore, the first layer 30A may define the area for collector implanting.

FIG. 1H shows the structure of FIG. 1G after implanting a collector 16A in the collector region 16. In some examples, an additional mask may be used for the implanting, however other examples may implant the collector 16A without an additional mask. The collector 16A may have a doping gradient in the vertical direction. Furthermore, the lateral dimensions of the cavity and the thickness of the first layer 30A may be selected such that a portion of the collector region 16 is less doped or not doped by the implanting process. Accordingly, as can be seen in FIG. 1H, an extrinsic collector region 16B may surround the collector 16A. In the extrinsic collector region 16B, the doping is significantly less than in the collector 16A. The collector 16A can in this example also be regarded as an intrinsic collector region. However, in other examples the lateral dimensions of the cavity and the thickness of the first layer 30A may be selected such the collector 16A is formed along the complete lateral dimension of the collector region 16. Accordingly, in such examples no extrinsic collector region may be formed.

After implanting the collector 16A, the first insulation layer 22 is removed in the emitter window area and below a portion of the first layer 30A. Removing of the first insulation layer 22 may include etching of the first insulation layer 22 using the first layer 30A as a mask to protect any etching of the conductive layer 24. The etching has to be timed such that the first layer 30A is completely removed in the area defined by the first layer 30A and in addition completely under a portion of the first layer 30A. Accordingly the first layer 30A needs to be under-etched to define a gap 32 between the under-etched portion of the first layer 30A and the collector region 16. The etching has further to be timed such that the conductive layer 24 remains sealed by the first insulation layer 22 and the first layer 30A. In other words, the etching has to be timed to avoid a complete under-etching of the first layer 30A which would result in a contact of the conductive layer 24 with the etchant. A contact of the conductive layer 24 with the etchant would significantly deteriorate the performance of the vertical RF bipolar transistor.

In some examples, the thickness of the first layer 30A is chosen in such way that after subsequent etching sequences of the first insulation layer 22 a portion of the first insulation layer 22 still remains underneath the layer 30A and covering the conductive layer 24.

The etching may be wet-etching or dry-etching or a combination thereof. Using wet-etching is less aggressive and may allow a better control of a forming of the gap 32 without breaking a sealing of the conductive layer 24. In one example, a dry etching is performed followed by a wet-etching. The dry-etching basically acts thereby without lateral removal and removes the first insulation layer 22 in the region defined by the inner walls of the first layer 30A. The wet-chemical etching basically removes the material under the first layer 30A to form the gap 32. FIG. 1I shows the structure after the etching with the gap 32 formed between a portion of the first layer 30A and the collector region 16.

In a following step, a base 34 is deposited by epitaxial growing. The epitaxial growing may be a selective epitaxial growing such that semiconductor material is growing only from the monocrystalline material of the collector region 16. Growing the base 34 may in examples include a growing of a plurality of base layers including for example a SiGe layer and a cap layer. The base 34 may have in one example a lateral dimension between 50 and 400 nm. FIG. 1J shows the structure after the growing of the base 34. It is to be noted that a lower portion of the base 34 extends in a lateral direction pointing away from a center axis C further than the inner sidewalls (sidewalls facing towards the center axis C of the vertical RF bipolar transistor) of the first layer 30A due to the gap 32 formed in the previous step. An upper portion of the base 34 extends in a lateral direction pointing away from the center axis C not further than the inner sidewalls of the first layer 30A. In other words, the base 34 may have different lateral dimensions for different vertical levels with the upper part being smaller than the lower part. This additionally increases the contact area between the base and the base link thus helping to further reduce the overall base resistance. Relative terms such as “outer” and “inner” or “outward” and “inward” may be regarded to be relative to the center axis C (e.g., outwards being pointing away from the center axis C and inwards being pointing towards the center axis C). The center axis C may for example be determined by a virtual vertical line through the arithmetic midpoint of an area of the base when viewed from the top.

After the forming of the base, a lower end of the first layer 30A is in the vertical direction arranged between a lower level of the base 34 and an upper level of the base 34.

In a next step, a further insulation layer 36 is deposited. As can be observed from FIG. 1K, the further insulation layer 36 extends in the cavity on the inner sidewalls of the first layer 30A and on the upper surface of the base 34. Outside of the cavity, the further insulation layer 36 extends on the upper surface of the second insulation layer 26. The further insulation layer 36 may for example include oxide material or other electrically insulating material. It is to be noted that the further insulation layer 36 may in other examples include a layer system including a plurality of layers of different materials. The further insulation layer 36 is therefore to be considered as having one layer or more than one layer.

The further insulation layer 36 is etched to form a sidewall spacer 36A extending in the vertical or nearly vertical direction (e.g., less than 15° deviation from the vertical direction) on the inner sidewalls of the first layer 30A, see FIG. 1L. An anisotropic etching may be used in order to remove the lateral extending parts of the further insulation layer 36 to form the sidewall spacer 36A.

In a following step, emitter material 38 is deposited in the cavity and on the upper surface of the second insulation layer 26, see FIG. 1M. Emitter material 38 may include n-doped silicon having a net doping concentration in the range of 5×10¹⁹ cm⁻³ to 1×10²¹ cm⁻³.

The emitter material 38 deposited outside of the cavity is removed as shown in FIG. 1N. Removing includes etching or chemical mechanical polishing or a combination thereof. The emitter material 38 remains in the cavity and forms an emitter 38A. In some examples, the fabricated emitter 38A may have an extension in a lateral direction between 60 to 150 nm. In some examples the first layer 30A and the sidewall spacer 36A may be formed to extend non-vertical such that the lateral dimension of the emitter 38A increases in the vertical outward direction. The emitter 38A may be flush with the second insulation layer 26, e.g., at the same vertical level as the second insulation layer 26. In other examples, a further etching may be performed to further reduce the height of the emitter 38A in the cavity such that the vertical level of the emitter 38A is below the vertical level of the second insulation layer 26. Reducing the emitter height reduces the resistance of the emitter 38A.

Referring to FIG. 1O, a protective layer 40 is deposited after forming the emitter 38A. The protective layer 40 protects the emitter 38A during the further processing to generate the base connection. The protective layer 40 may be one layer or formed by multiple layers of different material.

A lithography mask 42 is deposited which extends above the emitter 38A and further lateral to the first layer 30A as shown in FIG. 1P.

Referring to FIG. 1Q, the protective layer 40 and the second insulation layer 26 are removed outside the mask area by etching allowing access to the first layer 30A. The second insulation layer 26 may have a material different from the material of the first layer 30A such that the etching stops at the outer sidewall of the first layer 30A. After the etching, an outer sidewall of a first portion of the first layer 30A is exposed. In other words, no further layer is in direct contact with the outer sidewall of the first portion of the first layer 30A. A second portion of the first layer 30A which is in a lateral direction arranged between the base 34 and the conductive layer 24 and in direct contact with the base 34 and the conductive layer 24 remains unexposed. Furthermore, a third portion of the first layer 30A which is in a lateral direction arranged between the sidewall spacer 36A and the conductive layer 24 and in direct contact with the sidewall spacer 36A and the conductive layer 24 remains also unexposed.

The first layer 30A is thereafter removed by etching from the exposed outer wall. The etching leaves an empty space 46 between the base 34 and the conductive layer 24, see FIG. 1S. Since the first layer 30A is extending prior to the removing in a vertical or nearly vertical direction with a shape similar to a sidewall spacer, the amount of material that is removed by the etching is reduced and a good control of the etching is achieved. Another advantage of such approach is that material of the first layer 30A is different from material of the sidewall spacer 36A. This results in a well-controlled etching process and selectivity, ensuring an integrity of the side wall spacer 36A and enabling the separation of the base link region from the emitter. Isotropic etching may be used for removing the first layer 30A. Removing the first layer 30A results in exposing surface portions of the base 34 in a horizontal and vertical direction. Furthermore, a sidewall of the conductive layer 24 is exposed by removing the first layer 30A.

After forming the empty space 46 the structure is prepared for connecting the base 34 with the conductive layer 24. To this end, highly doped semiconductor material is deposited in the empty space 46 by selective epitaxial growing. In the regions close to the surfaces of the base 34, the semiconductor material will be monocrystalline which provides a high quality electrical connection. As noted above, due to the empty space 46 contacting the base 34 in a vertical and horizontal direction, the exposed surface of the base 34 is increased compared with a growing only from a vertical exposed surface. A lower end of the empty space 46 in a vertical direction is between a lower surface of the base 34 and an upper surface of the base 34. In other words, the empty space 46 does not extend to the collector region 16 and there will be no connection with the collector region 16 which further reduces parasitic effects and improves the characteristic.

The conductive layer 24 acts during the epitaxial growing as a seed layer allowing to grow polycrystalline material on the conductive layer 24. Due to the high doping of the conductive layer 24 and the semiconductor material growing on the conductive layer 24, a high quality electrical connection can be established. As can be observed in FIG. 1T, the thickness of the conductive layer 24 is increased due to the growing of semiconductor material. It is to be noted that the sidewall spacer 36A prevents that the grown semiconductor material gets into contact with the upper surface of the base 34. The former empty space 46 is now filled with doped semiconductor material forming an interface region 46A between the base 34 and the thickness extended conductive layer 24. In view of the high degree of monocrystalline material in the interface region 46A in combination with the conductive layer 24 having a high doping concentration, a high quality electrical base link with low electric resistance is achieved.

In a further step, the remaining protective layer 42 is removed, see FIG. 1U. A lithography mask 48 is formed covering the emitter 38A, the sidewall spacer 36A and a portion of the conductive layer 24 as shown in FIG. 1V. Thereafter, the thickness extended conductive layer 24 and the first insulation layer 22 are etched using the lithography mask 48. The remaining part of the thickness extended conductive layer 24 forms a base connection 24A that is electrically insulated towards the substrate by the remaining part 22A of first insulation layer 22, see FIG. 1W. The lithography mask 48 is then removed as shown in FIG. 1X.

A silicidation and metallization process is applied to further enhance the conductivity and prepare the structure for providing contact structures. FIG. 1Y shows the structure after the silicidation and metallization process. As can be seen, the upper portion of the emitter 38a is converted to a metallized silicide region 38B, the upper portion of the base connection 24A is converted to a metallized silicide region 24B and the upper region or the collector connection region 18 is converted to a metallized silicide region 18A.

After the silicidation, conventional processing steps including forming contacts to the emitter 38A, the collector connection region 18 and the base connection 24A may be used for completing the semiconductor device. In some examples of a BiCMOS process, CMOS transistors arranged in the substrate 10 may be formed prior to the described process, after the described process or completed after the described process. Such processing steps are conventional and will not be described herein.

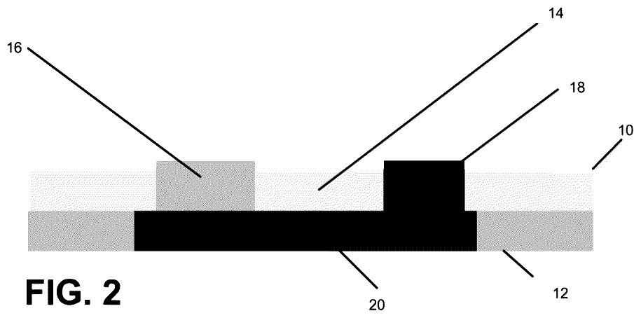

FIG. 2 shows a modification of the initial structure of FIG. 1A used in the manufacturing process. In the manufacturing process using the structure of FIG. 2 as initial structure, the insulation portion 14, which may for example include a shallow trench isolation oxide, is thinned with respect to the collector region 16. As can be seen, the upper surface of the collector region 14 is therefore elevated from the upper surface of the insulation portion 14. Using the processing steps as described in FIGS. 1B to 1Y in a similar manner on the initial substrate shown in FIG. 2 results in a vertical RF bipolar transistor in which the base 34 is more elevated from the insulation portion 14. Furthermore, using the initial structure shown in FIG. 2 for manufacturing a vertical RF bipolar transistor in which the lateral extension D1 of the collector region 16 at the collector-base interface is equal or smaller than the lateral extension D2 of the base at the collector-base interface may further increase the performance of the vertical RF bipolar transistor.

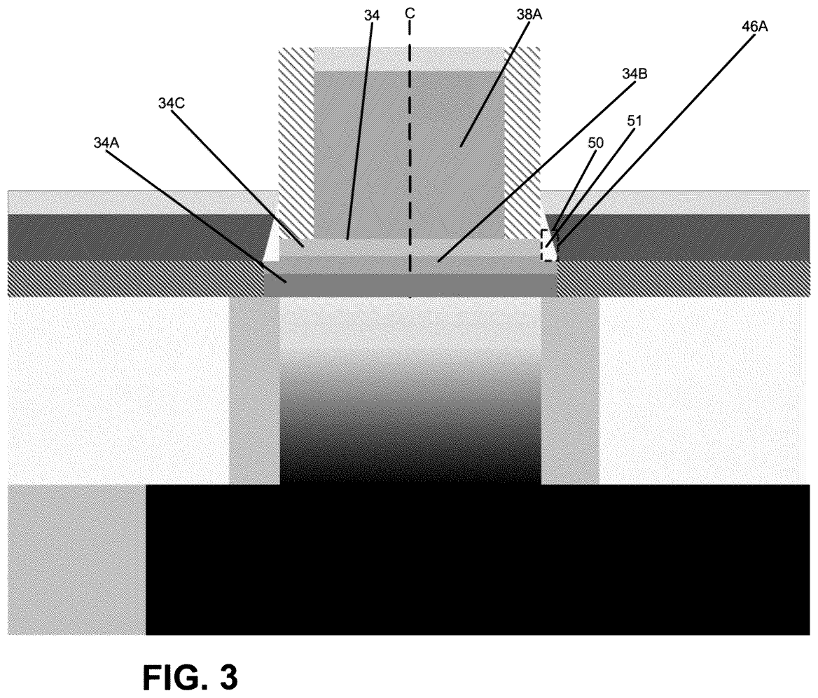

A more detailed schematic cross-sectional view of an example of a vertical RF bipolar transistor which can be manufactured as described above is shown in FIG. 3. In FIG. 3, the base 34 is shown to include multiple base layers 34A, 34B and 34C. The lowest base layer 34A is a SiGe layer with a high concentration of Germanium. The intermediate base layer 34B is a SiGe layer with a Germanium concentration less than in the lowest base layer 34A. While FIG. 3 shows the base layers 34A and 34B as separate layers it is to be noted that in other examples the Germanium concentration may continuously decrease from the lower part to the upper part such that the layers 34A and 34B are replaced by one layer with degrading Germanium concentration.

The top base layer 34C is a cap layer with Si or SiGe of very low Germanium concentration.

FIG. 3 further shows a monocrystalline region 50 and a polycrystalline region 51 of the base link. The interface region 46A between the base 34 and the base connection 24A defined by the former empty space 46 is shown in dashed lines. It can be observed that the interface region 46A overlaps in a top view (view in the direction of the vertical axis) with the base 34. In more detail, the interface region 46A overlaps in the top view with the lower part of the base 34. However, due to the use of the sacrificial first layer 30A in the manufacturing process described above, the interface region 46A is not in direct contact with the upper surface of the base 34. In other words, the interface region 46A does in a top view not overlap with the upper surface of the base and accordingly the interface region 46A does not extend over the upper surface of the base 34 (here the top base layer 34C). As the interface region 46A does not extend over the upper surface of the base 34, no area of the upper surface of the base 34 is occupied by the interface region. This allows to maximize the area available for forming a base-emitter interface which makes the concept very suitable for shrinking. Furthermore, parasitic effects can be reduced.

It can be noted that the interface region 46A includes a high degree of highly conductive monocrystalline material 50. In examples, the volume of monocrystalline material 50 in the interface region 46A compared to the volume of polycrystalline material in the interface region 46A is at least 20% in some examples at least 50%. It can further be observed that the interface region 46A is in a lateral direction extending closer towards the center axis C of the vertical RF bipolar transistor than the insulation layer 22A. In other words, the interface region 46A is arranged in the lateral direction closer to the center axis C than the insulation layer 22A. Furthermore, as can be observed from FIG. 3, the interface region 46A is in a direct contact with an outer surface of the sidewall spacer 36A. Therefore, a defined electrical isolation between the emitter 38A and the interface region is provided by the sidewall spacer 36A.

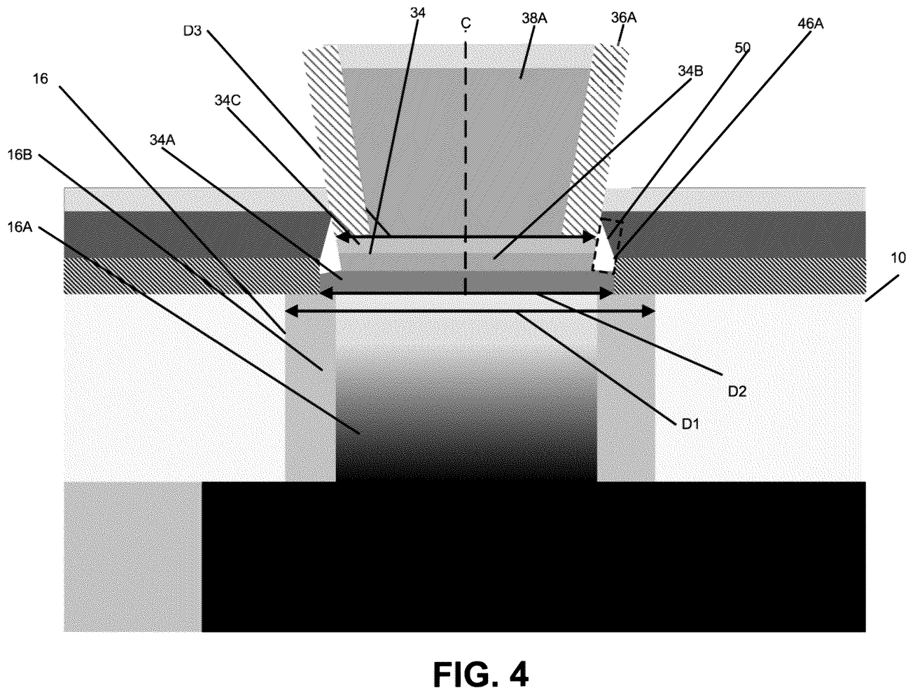

FIG. 4 shows a schematic cross-sectional view of a further example of a vertical RF bipolar transistor which can be manufactured as described above. In the vertical RF bipolar transistor according to FIG. 4, the sidewall spacer 36 is manufactured to be non-vertical. As a result, the lateral dimension of the emitter 38A is increasing in a direction pointing away from the substrate 10. Such non-vertical emitter due to its lateral expanding towards the top has additional advantage for the emitter resistance, making the emitter resistance lower. It is to be noted that the non-vertical sidewall spacer 36A and the increasing lateral dimension of the emitter 38A are not limited to the example of FIG. 4 but can be applied to any of the examples described herein. The non vertical shape is achieved by a non-uniform etching of the cavity defining the first layer 30A and the sidewall spacer 36A.

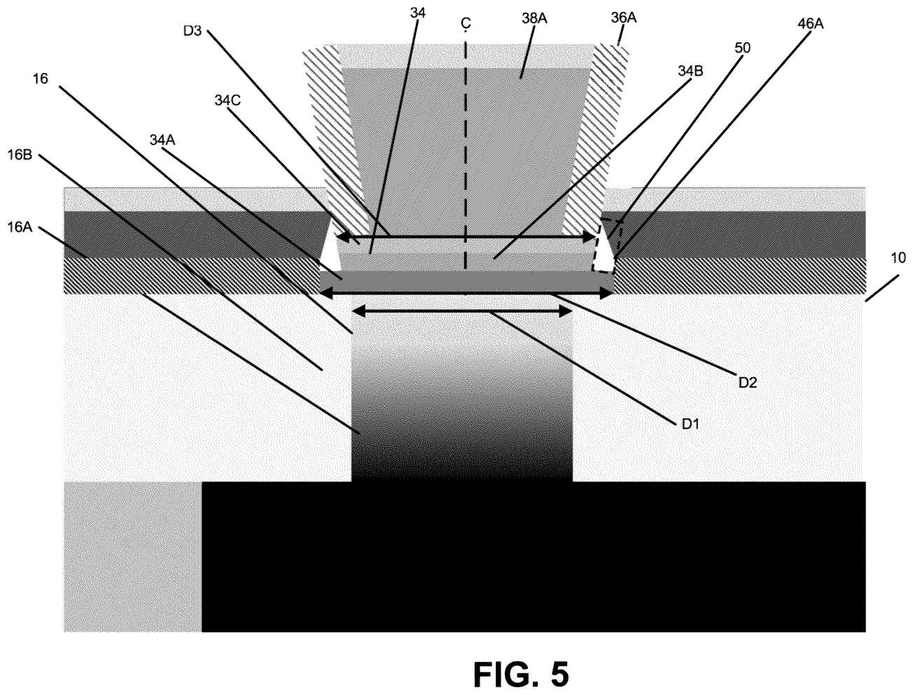

FIG. 5 shows a schematic cross-sectional view of a further example of a vertical RF bipolar transistor which can be manufactured as described above. The example is a modification of the vertical RF bipolar transistor shown in FIG. 4. In the vertical RF bipolar transistor according to FIG. 4, the lateral extension D1 of the collector region 16 at the collector-base interface is larger than the lateral extension D2 of the base at the collector-base interface. Distinguished therefrom, in the vertical RF bipolar transistor according to FIG. 5, the lateral extension D1 of the collector region 16 at the collector-base interface is reduced to a value smaller than the lateral extension D2 of the base 34 at the collector-base interface. The collector region 16 according to FIG. 5 does no longer include an extrinsic region 16B. The reduction of the lateral extension of the collector region 16 further reduces parasitic effects (e.g., parasitic emitter-collector capacitances) and increases the maximum frequency of operation to even higher frequencies. Furthermore in FIGS. 4 and 5, a lateral distance D3 between lateral outer boundary locations of the lower portion of the side spacers 36A is less than the lateral extension D2 of the base 34. In other words, an outer boundary of at least a portion of the sidewall spacer 36A (for example the lower portion of the sidewall spacer 36A) is therefore in a lateral direction closer to the center axis C of the vertical RF bipolar transistor than an outer boundary of the base 34.

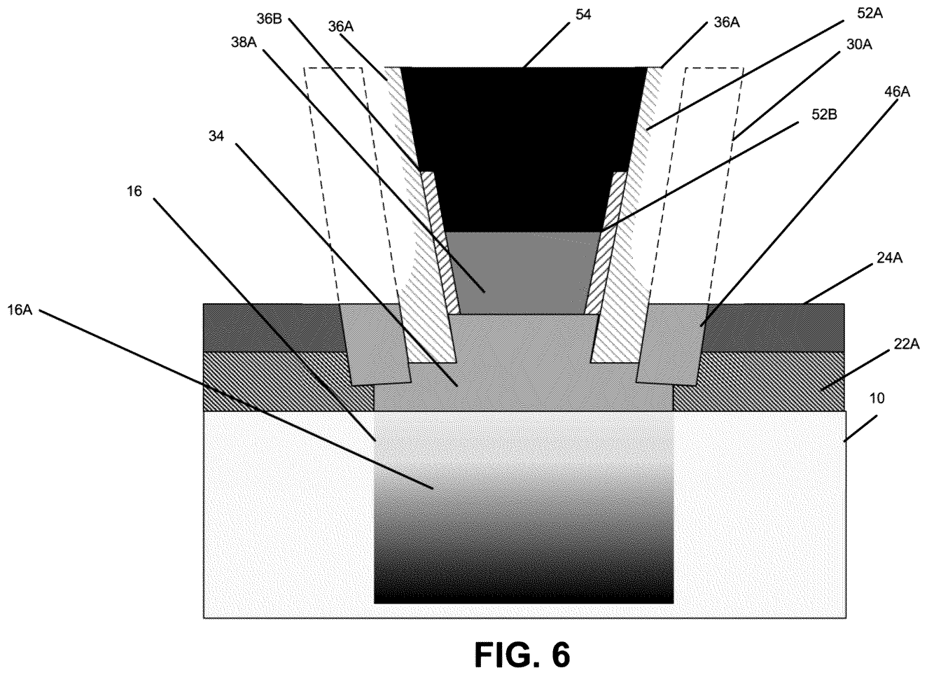

FIG. 6 shows a schematic cross-sectional view of a further example of a vertical RF bipolar transistor which can be manufactured as described above. In the example of FIG. 6, the sidewall spacer 36A is formed by an electrical insulation layer 52A and an additional electrical insulation layer 52B. Such approach additionally strengthens the spacer integrity. A thickness of at least one of the electrical insulation layers 52A and 52B (here the electrical insulation layer 52A) is decreasing in the vertical direction pointing away from the substrate 10. As can be seen from FIG. 6, the electrical insulation layer 52A is thinned in an upper region. For better understanding, the region corresponding to the removed first layer 30A is also shown in dashed lines. FIG. 6 further shows an emitter metal contact 54 contacting the emitter 38A from the top. As can be observed, the emitter 38A is arranged between respective portions of the electrical insulation layer 52A and also between respective portions of the further electrical insulation layer 52B of the sidewall spacer 36A. An upper portion of the emitter metal contact 54 is however arranged only between respective portions of the electrical insulation layer 52A and not between respective portions of the further electrical insulation layer 52B. In addition, the emitter metal contact 54 is arranged between respective thinned portions of the electrical insulation layer 52A, thus enabling a concept of self-aligned contact. While FIG. 6 shows the sidewall spacer 36A to include two electrical insulation layers 52A and 52B, it is to be noted that the sidewall spacer 36A may in other examples include a layer arrangement having more than two electrical insulation layers or only one electrical insulation layer.

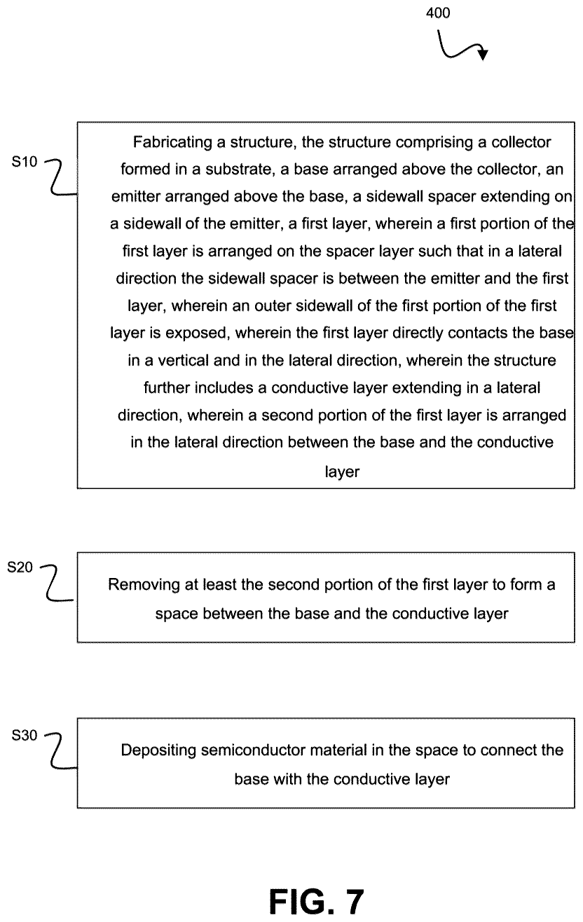

Referring now to FIG. 7, an example diagram of acts of the manufacturing process will be described. The diagram starts with the act S10 of fabricating of a structure, the structure comprising a collector formed in a substrate, a base arranged above the collector, an emitter arranged above the base, a sidewall spacer extending on a sidewall of the emitter, a first layer, wherein a first portion of the first layer is arranged on the sidewall spacer such that in a lateral direction the sidewall spacer is between the emitter and the first layer, wherein an outer sidewall of the first portion of the first layer is exposed, wherein the first layer directly contacts the base in a vertical and in the lateral direction, wherein the structure further includes a conductive layer extending in a lateral direction, wherein a second portion of the first layer is arranged in the lateral direction between the base and the conductive layer The structure may for example be manufactured according to the manufacturing acts described with respect to FIGS. 1A to 1R but is not limited thereto.

After fabricating the structure, at least the second portion of the first layer is removed to form a space between the base and the conductive layer, see act S20. The removing of the first layer and the resulting structure may for example be according to FIG. 1S and the corresponding description but is not limited thereto.

Act S30 includes depositing semiconductor material in the space to connect the base with the conductive layer. Act S30 and the resulting structure may for example be according to FIG. 1U and the corresponding description but is not limited thereto.

A new concept for manufacturing a vertical RF bipolar transistor has been described. As outlined already above, this concept enables vertical RF bipolar transistors to be capable of operating in very high or extreme RF frequencies. Furthermore, the new concepts allows the vertical RF bipolar transistors to have high quality electrical behavior with low parasitic effects and low power loss. The process can be easily integrated into a BiCMOS process.

### Aspects

In addition to the above aspects, the following aspects of the concept described herein are presented.

Aspect 1 is a method of manufacturing a vertical RF bipolar transistor, the method comprising:
fabricating a structure, the structure comprising
a collector (16A) formed in a substrate (10),
a base (34) arranged above the collector (16A),
an emitter (38A) arranged above the base (34),
a sidewall spacer (36A) extending on a sidewall of the emitter (38A),
a first layer (30A), wherein a first portion of the first layer (30A) is arranged on the sidewall spacer (36A) such that in a lateral direction the sidewall spacer (36A) is between the emitter (38A) and the first layer (30A) and wherein an outer sidewall of the first portion of the first layer (30A) is exposed, wherein the first layer (30A) directly contacts the base (34) in a vertical direction and in the lateral direction,
a conductive layer (24) extending in the lateral direction,
wherein a second portion of the first layer (30A) is arranged in the lateral direction between the base (34) and the conductive layer (24),
after fabricating the structure, removing at least the second portion of the first layer (30A) to form a space (46) between the base (34) and the conductive layer (24), and
depositing semiconductor material in the space (46) to connect the base (34) with the conductive layer (24).

Aspect 2 is the method according to aspect 1, wherein the sidewall spacer (36A) is an arrangement of multiple layers (52A, 52B).

Aspect 3 is the method according to aspect 1 or 2, wherein depositing semiconductor material comprises growing semiconductor material in the space (46) and wherein during the growing of semiconductor material in the space (46) further semiconductor material is grown on the conductive layer (24) to increase a thickness of the conductive layer (24).

Aspect 4 is the method according to any of the preceding aspects, wherein depositing semiconductor material in the space (46) comprises epitaxial growing of crystalline semiconductor material in the space (46).

Aspect 5 is the method according to aspect 4, wherein the epitaxial growing of crystalline semiconductor material in the space (46) comprises at least partially growing monocrystalline semiconductor in the space (46).

Aspect 6 is the method according to any of the preceding aspects, wherein the sidewall spacer (36A) is in direct contact with the base (34).

Aspect 7 is the method according to any of the preceding aspects, wherein the base (34) extends in a vertical direction between a lower base level and an upper base level and wherein a lower end of the first layer (30A) is in the vertical direction between the lower base level and the upper base level.

Aspect 8 the method according to any of the preceding aspects, wherein the first layer (30A) directly contacts the conductive layer (24) in the lateral direction.

Aspect 9 is the method according to any of the preceding aspects, further comprising generating a mask (48) covering the emitter (38A), the sidewall spacer (36A) and a portion of the conductive layer (24) and structuring the conductive layer (24) using the mask (48) after depositing semiconductor material in the space (46).

Aspect 10 is the method according to any of the preceding aspects, wherein fabricating the structure comprises:
generating a stack of layers on the substrate (10), the stack of layers comprising a first electrical insulation layer (22), the conductive layer (24) and a second electrical insulation layer (26),
forming a cavity by removing a portion of the second electrical insulation layer (26) and a portion of the conductive layer (24) in a cavity area, wherein the conductive layer (24) remains outside the cavity area, and
forming the first layer (30A) on a sidewall of the cavity, wherein the first layer (30A) defines a first window and wherein the first layer (30A) extends on a sidewall of the conductive layer (24) and wherein the first layer (30A) directly contacts a surface of the first electrical insulation layer (22).

Aspect 11 is the method according to aspect 10, wherein the first layer (30A) directly contacts the surface of the first electrical insulation layer (22) in a vertical direction.

Aspect 12 is the method according to aspect 11, wherein the first layer (30A) comprises material that is different from a material of the first electrical insulation layer (22), the method further comprising etching the first electrical insulation layer (22) to partially expose a surface of the second portion of the first layer (30A).

Aspect 13 is the method according to aspect 12, further comprising:
etching the first electrical insulation layer (22) in an area of the first window and partially below the first layer (30A) to form a gap (32) below the first layer (30A), and
growing the base (34) in the first window and in the gap (32).

Aspect 14 is the method according to any of aspects 12 or 13, further comprising: doping the collector (16A) via the first window prior to the etching of the first electrical insulation layer (22).

Aspect 15 is the method according to any of aspects 12 to 14, further comprising forming the sidewall spacer (36A) on the first layer (30A) to define an emitter area, and forming the emitter (38A) in the emitter area.

Aspect 16 is the method according to any of the preceding aspects, wherein removing the first layer (30A) comprises removing the first layer (30A) completely.

Aspect 17 is the method according to any of the preceding aspects, wherein the first layer (30A) has a thickness in the lateral direction of less than 100 nm.

Aspect 18 is the method according to any of the preceding aspects, wherein the structure is arranged in a shallow trench, wherein the collector (16A) is surrounded by a shallow trench isolation material (14).

Aspect 19 is a vertical RF bipolar transistor comprising:
a substrate (10) comprising a first main surface,
a collector (16A) arranged in the substrate (10),
a base (34) arranged above the collector (16A),
an emitter (38A) arranged above the base (34),
a sidewall spacer (36A) arranged lateral to the emitter (38A),
an insulation layer (22A) arranged above the first main surface of the substrate (10),
a base connection (24A), wherein the base connection (24A) extends in a lateral direction on the insulation layer (22A),
a conductive interface region (46A), the conductive interface region (46A) electrically connecting the base connection (24A) with the base (34), the conductive interface region (46A) comprising monocrystalline semiconductor material,
wherein the base (34) and the conductive interface region (46A) overlap in a top view and wherein the conductive interface region (46A) is not in direct contact with an upper surface of the base (34).

Aspect 20 is the vertical RF bipolar transistor according to aspect 19, wherein the monocrystalline semiconductor material of the conductive interface region (46A) is in a top view arranged within a collector region (16).

Aspect 21 is the vertical RF bipolar transistor according to aspect 19, wherein a dimension of the collector (16A) in a lateral direction is smaller than a dimension of the base (34) in the lateral direction.

Aspect 22 is the vertical RF bipolar transistor according to any of aspects 19 to 21, wherein an outer boundary of at least a portion of the sidewall spacer (36A) is in a lateral direction closer to a center axis of the vertical RF bipolar transistor than an outer boundary of the base (34).

Aspect 23 is the vertical RF bipolar transistor according to any of aspects 19 to 22, wherein the conductive interface region (46A) is arranged in a lateral direction closer towards a center axis of the vertical RF bipolar transistor than the insulation layer (22A).

Aspect 24 is the vertical RF bipolar transistor according to any of aspects 19 to 23, wherein the conductive interface region (46A) is in direct contact with an outer surface of the sidewall spacer (36A).

Aspect 25 is the vertical RF bipolar transistor according to any of aspects 19 to 24, wherein the conductive interface region (46A) comprises monocrystalline material and polycrystalline material.

Aspect 26 is the vertical RF bipolar transistor according to any of aspects 19 to 25, wherein the interface region (46A) is not in direct contact with the collector (16A).

Aspect 27 is the vertical RF bipolar transistor according to any of aspects 19 to 26, wherein the sidewall spacer (36A) comprises a plurality of electrical insulation layers (52A, 52B), wherein a thickness of at least one of the electrical insulation layers (52A, 52B) is decreasing in a vertical direction pointing away from the substrate (10).

Aspect 28 is a semiconductor device comprising a vertical RF bipolar transistor according to any of aspects 19 to 27.

Although specific aspects have been illustrated and described herein, it will be appreciated by those of ordinary skill in the art that a variety of alternate and/or equivalent implementations may be substituted for the specific aspects shown and described without departing from the scope of the present implementation. This application is intended to cover any adaptations or variations of the specific aspects discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all aspects and implementations outlined in the present document are principally intended expressly to be only for explanatory purposes to help the reader in understanding the principles of the proposed methods and systems. Furthermore, all statements herein providing principles, aspects, and implementations of the implementation, as well as specific aspects thereof, are intended to encompass equivalents thereof.

1. A method of manufacturing a vertical radio frequency (RF) bipolar transistor, the method comprising:
fabricating a structure, the structure comprising
a collector formed in a substrate,
a base arranged above the collector,
an emitter arranged above the base,
a sidewall spacer extending on a sidewall of the emitter,
a first layer, wherein a first portion of the first layer is arranged on the sidewall spacer such that in a lateral direction the sidewall spacer is between the emitter and the first layer and wherein an outer sidewall of the first portion of the first layer is exposed, wherein the first layer directly contacts the base in a vertical direction and in the lateral direction,
a conductive layer extending in the lateral direction,
wherein a second portion of the first layer is arranged in the lateral direction between the base and the conductive layer,
after fabricating the structure, removing at least the second portion of the first layer to form a space between the base and the conductive layer, and
depositing semiconductor material in the space to connect the base with the conductive layer.

2. The method according to claim 1, wherein the sidewall spacer is an arrangement of multiple layers.

3. The method according to claim 1,
wherein depositing semiconductor material comprises growing semiconductor material in the space, and
wherein during the growing of semiconductor material in the space further semiconductor material is grown on the conductive layer to increase a thickness of the conductive layer.

4. The method according to claim 1, wherein depositing semiconductor material in the space comprises epitaxial growing of crystalline semiconductor material in the space.

5. The method according to claim 4, wherein the epitaxial growing of crystalline semiconductor material in the space comprises at least partially growing monocrystalline semiconductor in the space.

6. The method according to claim 1, wherein the sidewall spacer is in direct contact with the base.

7. The method according to claim 1, wherein the base extends in a vertical direction between a lower base level and an upper base level and wherein a lower end of the first layer is in the vertical direction between the lower base level and the upper base level.

8. The method according to claim 1, wherein the first layer directly contacts the conductive layer in the lateral direction.

9. The method according to claim 1, further comprising generating a mask covering the emitter, the sidewall spacer and a portion of the conductive layer and structuring the conductive layer using the mask after depositing semiconductor material in the space.

10. The method according to claim 1, wherein fabricating the structure comprises:
generating a stack of layers on the substrate, the stack of layers comprising a first electrical insulation layer, the conductive layer and a second electrical insulation layer,
forming a cavity by removing a portion of the second electrical insulation layer and a portion of the conductive layer in a cavity area, wherein the conductive layer remains outside the cavity area, and
forming the first layer on a sidewall of the cavity, wherein the first layer defines a first window and wherein the first layer extends on a sidewall of the conductive layer and wherein the first layer directly contacts a surface of the first electrical insulation layer.

11. The method according to claim 10, wherein the first layer directly contacts the surface of the first electrical insulation layer in a vertical direction.

12. The method according to claim 11, wherein the first layer comprises material that is different from a material of the first electrical insulation layer, the method further comprising etching the first electrical insulation layer to partially expose a surface of the second portion of the first layer.

13. The method according to claim 12, further comprising:
etching the first electrical insulation layer in an area of the first window and partially below the first layer to form a gap below the first layer, and
growing the base in the first window and in the gap.

14. The method according to claim 12, further comprising:
doping the collector via the first window prior to the etching of the first electrical insulation layer.

15. The method according to claim 12, further comprising:
forming the sidewall spacer on the first layer to define an emitter area, and
forming the emitter in the emitter area.

16. The method according to claim 1, wherein removing the first layer comprises removing the first layer completely.

17. The method according to claim 1, wherein the first layer has a thickness in the lateral direction of less than 100 nm.

18. The method according to claim 1, wherein the structure is arranged in a shallow trench, wherein the collector is surrounded by a shallow trench isolation material.

19. A vertical radio frequency (RF) bipolar transistor comprising:
a substrate comprising a first main surface,
a collector arranged in the substrate,
a base arranged above the collector,
an emitter arranged above the base,
a sidewall spacer arranged lateral to the emitter,
an insulation layer arranged above the first main surface of the substrate,
a base connection, wherein the base connection extends in a lateral direction on the insulation layer,
a conductive interface region, the conductive interface region electrically connecting the base connection with the base, the conductive interface region comprising monocrystalline semiconductor material,
wherein the base and the conductive interface region overlap in a top view and wherein the conductive interface region is not in direct contact with an upper surface of the base.

20. The vertical RF bipolar transistor according to claim 19, wherein the monocrystalline semiconductor material of the conductive interface region is in a top view arranged within a collector region.

21. The vertical RF bipolar transistor according to claim 19, wherein a dimension of the collector in a lateral direction is smaller than a dimension of the base in the lateral direction.

22. The vertical RF bipolar transistor according to claim 19, wherein an outer boundary of at least a portion of the sidewall spacer is in a lateral direction closer to a center axis of the vertical RF bipolar transistor than an outer boundary of the base.

23. The vertical RF bipolar transistor according to claim 19, wherein the conductive interface region is arranged in a lateral direction closer towards a center axis of the vertical RF bipolar transistor than the insulation layer.

24. The vertical RF bipolar transistor according to claim 19, wherein the conductive interface region is in direct contact with an outer surface of the sidewall spacer.

25. The vertical RF bipolar transistor according to claim 19, wherein the conductive interface region comprises monocrystalline material and polycrystalline material.

26. The vertical RF bipolar transistor according to claim 19, wherein the conductive interface region is not in direct contact with the collector.

27. The vertical RF bipolar transistor according to claim 19,
wherein the sidewall spacer comprises a plurality of electrical insulation layers, and
wherein a thickness of at least one of the electrical insulation layers is decreasing in a vertical direction pointing away from the substrate.

28. (canceled)
